(19) United States
(12) Patent Application Publication
(10) Pub. No.: US 2011/0111549 A1
(43) Pub. Date: May 12, 2011

(54) Image Sensor with Pixel Wiring to Reflect Light

(76) Inventor: Hiok Nam TAY, Singapore (SG)

(21) Appl. No.: 13/011,864

(22) Filed: Jan. 22, 2011

Related U.S. Application Data
(63) Continuation of application No. 11/716,172, filed on Mar. 9, 2007, now abandoned.

(51) Int. Cl. H01L 31/18

(52) U.S. Cl. 438/72; 257/E31.127; 257/E31.124

(57) ABSTRACT

An image sensor with a plurality of photodiodes pixels. At least one of the photodiodes pixels includes a reflective element that prevents light from traveling onto an adjacent photodiode pixel. The reflective element may be a floating contact adjacent a routing wire of the image sensor. The reflective element may have an aspect ratio that maximizes the reflective surface of the element.

### BACKGROUND OF THE INVENTION

1. Field of the Invention

The subject matter disclosed generally relates to the field of semiconductor image sensors.

2. Background Information

Photographic equipment such as digital cameras and digital camcorders may contain electronic image sensors that capture light for processing into still or video images, respectively. Electronic image sensors typically contain millions of light capturing elements such as photodiodes. The photodiodes are arranged in a two-dimensional pixel array.

FIG. 1 shows an enlarged perspective view of adjacent pixels in a photodiode array. Each pixel has a photo-absorption region 1 and 2, respectively, that absorbs incoming light 3 and creates electron hole pairs.

Wires 4 are formed on the surface of the array to route electrical signals to the individual pixels of the array. The wires 4 are spaced apart to form windows that allow light to travel into the photo-absorption regions 1 and 2. In the center of the array the light impinges onto the photo-absorption regions in an essentially perpendicular direction. In the outer corner regions of the array the light travels at an inclined direction such that some of the light that travels through the window of the first photo-absorption region 1 impinges on the second photo-absorption region 2, as shown in FIG. 1. This will cause the pixel of region 2 to inadvertently sense light from the first region and result in a lower quality picture.

It would be desirable to isolate pixels of a photodiode array to inhibit inadvertent light absorption from adjacent pixels.

### BRIEF SUMMARY OF THE INVENTION

An image sensor with an array of photodiodes pixels. At least one of the photodiodes pixels includes a reflective element that is adjacent to a routing wire and reflects light onto a photo-absorption region of the photodiode.

### BRIEF DESCRIPTION OF THE DRAWINGS

FIG. 1 is an illustration of an image sensor of the prior art;

FIG. 2 is a schematic of an image sensor;

FIG. 3 is an illustration of a photodiode pixel;

FIG. 4 is an illustration similar to FIG. 3 with a routing wire removed;

FIG. 5 is an illustration similar to FIG. 4 showing light being reflected from a hanging wire;

FIG. 6 is an illustration of an alternate embodiment of the photodiode pixel;

FIG. 7 is an illustration of an alternate embodiment of the photodiode pixel.

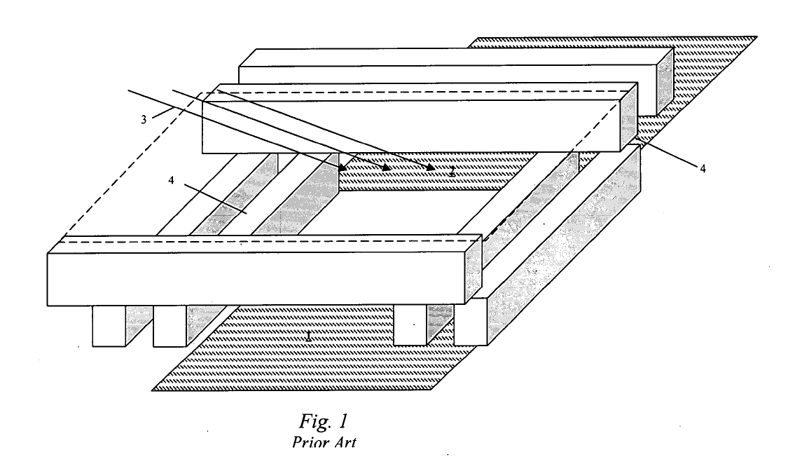

### DETAILED DESCRIPTION

Disclosed is an image sensor with a plurality of photodiodes pixels. At least one of the photodiodes pixels includes a reflective element that prevents light from traveling onto an adjacent photodiode pixel. The reflective element may be a floating contact adjacent a routing wire of the image sensor. The reflective element may have an aspect ratio that maximizes the reflective surface of the element.

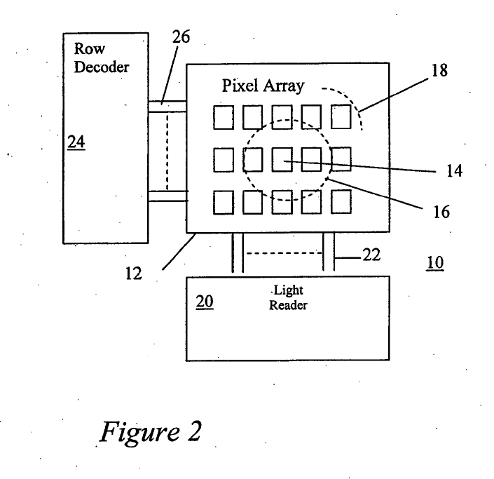

Referring to the drawings more particularly by reference numbers, FIG. 2 shows an image sensor 10. The image sensor 10 includes a photodiode pixel array 12 that contains a plurality of individual photodiodes 14. The photodiodes 14 are typically arranged in a two-dimensional array of rows and columns. The array 12 has a center area 16 and corner areas 18.

The photodiode array 12 is typically connected to a light reader circuit 20 by a plurality of routing wires 22. The array 12 is connected to a row decoder 24 by routing wires 26. The row decoder 24 can select an individual row of the array 12. The light reader 20 can then read specific discrete columns within the selected row. Together, the row decoder 24 and light reader 20 allow for the reading of an individual photodiode 14 in the array 12. The data read from the photodiodes 14 may be processed by other circuits such as a processor (not shown) to generate a visual display.

The image sensor 10 and other circuitry may be configured, structured and operated in the same, or similar to, the corresponding image sensors and image sensor systems disclosed in U.S. Pat. No. 6,795,117 issued to Tay, which is hereby incorporated by reference.

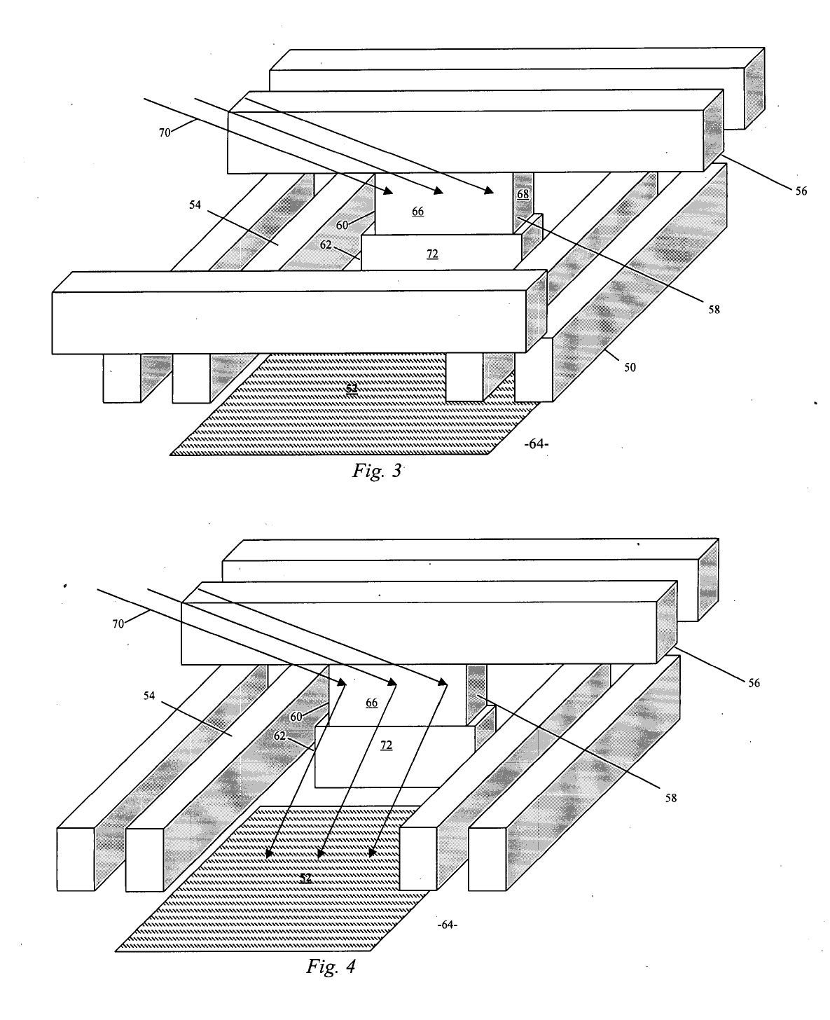

FIGS. 3 and 4 show a photodiode pixel 50. The pixel includes a photo-absorption region 52 of a photodiode. By way of example, the photo-absorption region 52 may be a lightly doped n-type material. Routing wires 54 and 56 extend across the face of the image sensor. Some of the routing wires are connected to the row decoder and light reader shown in FIG. 2.

Adjacent one or more of the wires 54 is a reflective element 58. The reflective element 58 may include a via 60 and a hanging wire 62. The reflective element 58 may be located between the wire 56 and a substrate 64. Each via 60 may include a width surface 66 and a thickness surface 68.

The reflective element 58 is constructed from a reflective material such as a metal to reflect incoming light 70 onto the photo-absorption region 52. By way of example, the metal may be copper, aluminum or any other metal used in the fabrication of semiconductor circuits.

In the outer areas of the pixel array light travels at an angle normal to the top surface of the image sensor. The reflective element 58 prevents the light from impinging upon an adjacent photodiode pixel. The reflective element 58 also reflects the light onto the photo-absorption region 52 to maximize the amount of light that impinges region 52. The via may have a width surface 66 to thickness surface 68 aspect ratio that maximizes the area of reflective surface 66. By way of example, the width to thickness ratio greater than 1, such as 1.5. This is to be distinguished from prior art via which require a 1 to 1 ratio. Likewise, by way of example, the hanging wire 62 may have a width surface 72 that is greater than one times the thickness of the wire 62. Although aspect ratios greater than 1 are shown and described, it is to be understood that the invention may utilize aspect ratios equal to or less than one for the via 60 and/or wire 62.

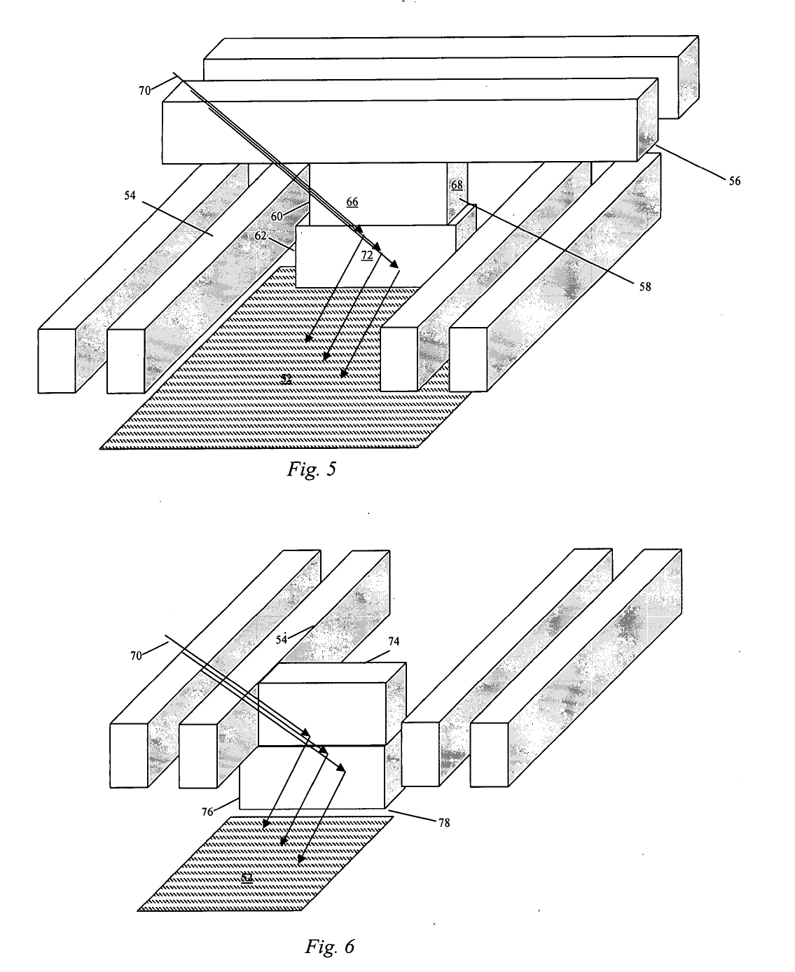

As shown in FIG. 5 deep penetrating light can be reflected by the hanging wire 62.

FIG. 6 shows an alternate embodiment, that has a hanging wire 74 and a floating contact 76. The hanging floating contact 76 is formed adjacent to a dielectric barrier 78. By way of example, the dielectric barrier 74 may be a layer of thick oxide. The barrier 74 electrically isolates the hanging wire 62 from the image sensor substrate so that the reflective element is a floating contact.

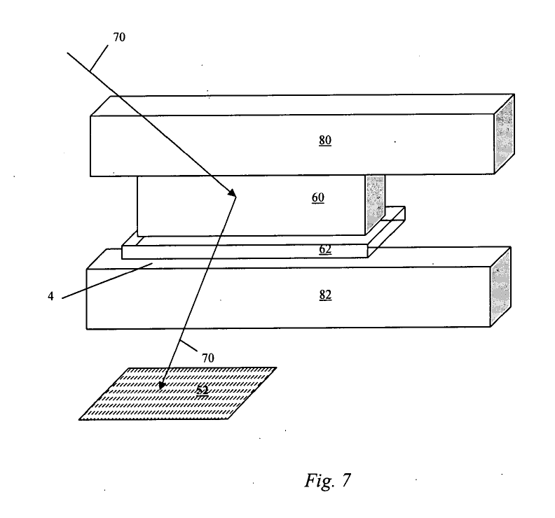

FIG. 7 is another alternate embodiment, where the via 60 and hanging wire 62 are located between two conductors 80 and 82. The hanging wire 62 may be separated from conductor 82 by a layer of dielectric 84 to prevent electrical shorting between the conductors 80 and 82.

The photodiodes may be constructed with known CMOS fabrication techniques. The photo-absorption region 52, and barrier 74 if desired, are formed on the substrate. Routing wires 54 and the hanging wire 62 are fabricated over region 52. The via 60 is formed on the hanging wire 62. Routing wires 56 are then fabricated. For the embodiment shown in FIG. 6, the routing wires 54 can be fabricated with the via 60. The order of formation may vary depending on the processes used to create the image, sensor.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

What is claimed is:

1. A method for forming an image sensor that includes a pixel array across a substrate, the pixel array comprising a photo-absorption region disposed under a light transmissive region, the method comprising:
forming a dielectric barrier on the substrate; and,
forming a contact on the dielectric barrier and insulated from the substrate by the dielectric barrier, the floating contact having a light-reflective lateral side facing and bounding the light transmissive region.

2. The method of claim 1, wherein the contact is elongated in a direction parallel to the light-reflective side.
